(19) United States
(12) Patent Application Publication
(10) Pub. No.: US 2018/0166362 A1
(43) Pub. Date: Jun. 14, 2018

(54) SEMICONDUCTOR STACKING STRUCTURE AND METHOD FOR MANUFACTURING THEREOF

(71) Applicant: NANYA TECHNOLOGY CORPORATION, Taoyuan City (TW)

(72) Inventor: Po-Chun LIN, Changhua County (TW)

(21) Appl. No.: 15/378,068

(22) Filed: Dec. 14, 2016

(51) Int. Cl. H01L 23/48; H01L 23/00; H01L 21/768

(52) U.S. Cl. CPC H01L 23/481; H01L 24/09; H01L 2224/0237; H01L 21/76898; H01L 24/17

(57) ABSTRACT

A semiconductor stacking structure is provided. The semiconductor stacking structure includes a substrate and at least one conductor. The substrate has at least one first through via formed at an edge of the substrate. The conductor is present in the first through via. At least one of the conductor and the first through via is exposed from the edge of the substrate.

### BACKGROUND

### Technical Field

The present disclosure relates to a semiconductor stacking structure.

### Description of Related Art

The semiconductor industry continues to improve the integration density of various electronic components (e.g., transistors, diodes, resistors, capacitors, etc.) by continual reductions in minimum feature size, which allows more components to be integrated into a given area. In some applications, these smaller electronic components also require smaller semiconductor chips that utilize less area than semiconductor chips of the past.

In practice, conductors are formed in the through vias of each of the semiconductor chips such that the semiconductor chips can be electrically connected with each other through the conductors. However, a keep-out-zone (KOZ) is easily developed around each of the conductors on the semiconductor chips. To be specific, KOZ is the region of the semiconductor chip around the conductor on where a field of stress is developed because of the shrinkage of the conductor. Generally speaking, the performance of the electronic components to be disposed on the KOZ may be influenced due to the field of stress developed.

### SUMMARY

A technical aspect of the present disclosure is to provide a semiconductor stacking structure, which can effectively minimize the size of the keep-out-zone (KOZ) on the substrate around the through via.

According to an embodiment of the present disclosure, a semiconductor stacking structure is provided. The semiconductor stacking structure includes a substrate and at least one conductor. The substrate has at least one first through via formed at an edge of the substrate. The conductor is present in the first through via. At least one of the conductor and the first through via is exposed from the edge of the substrate.

In one or more embodiments of the present disclosure, the conductor is substantially flushed with the edge of the substrate.

In one or more embodiments of the present disclosure, the semiconductor stacking structure further includes a passivation layer. The passivation layer is disposed on the substrate and has at least one second through via. The second through via is formed at an edge of the passivation layer and is communicated with the first through via, in which the conductor is further present in the second through via.

In one or more embodiments of the present disclosure, the semiconductor stacking structure further includes at least one metallic pad. The metallic pad is disposed on the passivation layer and contacts the conductor.

In one or more embodiments of the present disclosure, the semiconductor stacking structure further includes a bump. The bump is disposed on the metallic pad.

In one or more embodiments of the present disclosure, the semiconductor stacking structure further includes at least one metallic pad. The metallic pad is disposed on the passivation layer away from the edge of the passivation layer and is electrically connected with the conductor.

In one or more embodiments of the present disclosure, the semiconductor stacking structure further includes a first redistribution line. The first redistribution line is disposed on the passivation layer, in which the metallic pad is electrically connected with the conductor through the first redistribution line.

In one or more embodiments of the present disclosure, the semiconductor stacking structure further includes a bump. The bump is disposed on the metallic pad and covers at least a portion of the first redistribution line.

In one or more embodiments of the present disclosure, the semiconductor stacking structure further includes a metallic structure. The metallic structure is embedded in the passivation layer, in which the metallic pad is electrically connected with the conductor through the metallic structure.

In one or more embodiments of the present disclosure, the semiconductor stacking structure further includes a second redistribution line. The second redistribution line is disposed on a surface of the substrate away from the passivation layer.

In one or more embodiments of the present disclosure, the semiconductor stacking structure further includes a dielectric layer. The dielectric layer at least partially surrounds the conductor.

According to an embodiment of the present disclosure, a method for manufacturing a semiconductor stacking structure is provided. The method includes forming a first though via in a substrate; forming a conductor in the first through via; and etching the substrate to remove at least a part of the substrate to form an edge exposing at least one of a part of the conductor and a part of the first through via.

In one or more embodiments of the present disclosure, the step of etching includes etching the conductor such that the conductor is substantially flushed with the edge of the substrate.

In one or more embodiments of the present disclosure, the method further includes forming a second through via communicated with the first through via in a passivation layer disposed on the substrate; forming the conductor in the second through via; and etching the passivation layer to remove at least a part of the passivation layer such that at least a part of the conductor is exposed from the passivation layer.

When compared with the prior art, the above-mentioned embodiments of the present disclosure have at least the following advantages:

(1) Since the surface of the conductor is exposed to the air, even if the conductor present in the first via shrinks after the conductor is cooled down in consequence of the manufacturing process in a relatively higher temperature, the stress that the conductor exerts on the substrate because of the shrinkage of the conductor is effectively minimized. As a result, the size of the KOZ is also effectively minimized. Therefore, more amount of area on the substrate can be used for disposing electronic components such as transistors.

(2) Since the size of the KOZ on the substrate around the conductor and thus the through via is effectively minimized, the chance of deformation such as warpage of the semiconductor stacking structure is also effectively minimized.

### BRIEF DESCRIPTION OF THE DRAWINGS

The disclosure can be more fully understood by reading the following detailed description of the embodiments, with reference made to the accompanying drawings as follows:

FIG. 1 is a top view of a semiconductor stacking structure according to an embodiment of the present disclosure;

FIG. 2 is a sectional view along the section line X of FIG. 1;

FIG. 3 is a sectional view of a semiconductor stacking structure according to another embodiment of the present disclosure;

FIG. 4 is a top view of a semiconductor stacking structure according to a further embodiment of the present disclosure; and

FIG. 5 is a sectional view along the section line Y of FIG. 4.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

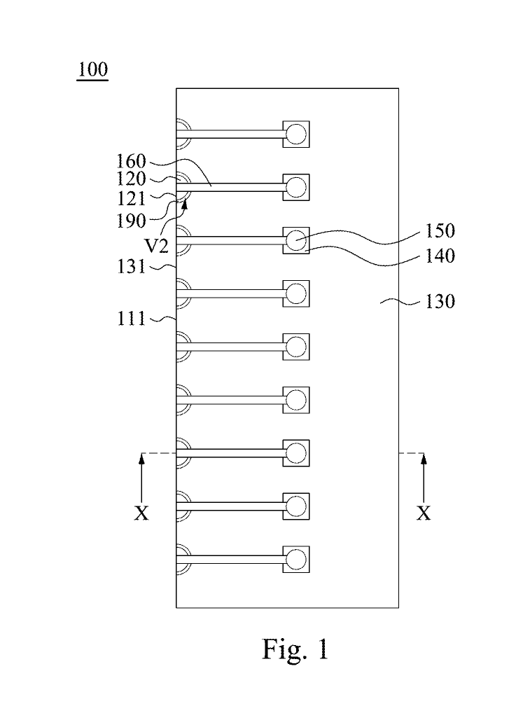

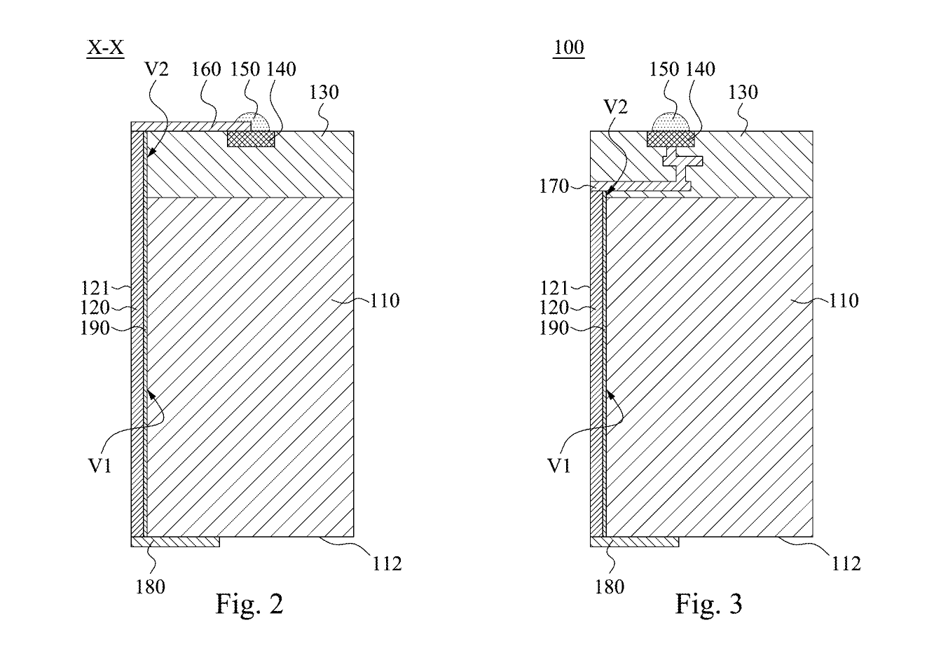

Reference is made to FIGS. 1-2. FIG. 1 is a top view of a semiconductor stacking structure 100 according to an embodiment of the present disclosure. FIG. 2 is a sectional view along the section line X of FIG. 1. As shown in FIGS. 1-2, a semiconductor stacking structure 100 is provided. The semiconductor stacking structure 100 includes a substrate 110 and at least one conductor 120. The substrate 110 has at least one first through via V1 formed at an edge 111 of the substrate 110. The conductor 120 is present in the first through via V1. At least one of the conductor 120 and the first through via V1 is exposed from the edge 111 of the substrate 110.

Structurally speaking, as shown in FIGS. 1-2, in case the conductor 120 is exposed from the edge 111 of the substrate 110, the surface 121 of the conductor 120 is exposed to the air. Meanwhile, the conductor 120 is partially surrounded by the substrate 110. In this way, since the conductor 120 at least partially contacts with the substrate 110 in practical applications, even if the conductor 120 present in the first through via V1 shrinks after the conductor 120 is cooled down in consequence of a manufacturing process in a relatively higher temperature, the stress that the conductor 120 exerts on the substrate 110 because of the shrinkage of the conductor 120 is effectively minimized. As a result, the size of the keep-out-zone (KOZ) is also effectively minimized. To be more specific, the KOZ is the region of the substrate 110 around the conductor 120 and thus the first through via V1 on where a field of stress is developed because of the shrinkage of the conductor 120. Practically speaking, electronic components (not shown) such as transistors to be disposed on the substrate 110 are kept out of the KOZ, so as to avoid the influence on the performance of the electronic components due to the field of stress developed on the substrate 110. In this embodiment, as mentioned above, since the size of the KOZ on the substrate 110 around the conductor 120 and thus the first through via V1 is effectively minimized, more amount of area on the substrate 110 can be used for disposing electronic components such as transistors.

Moreover, since the size of the KOZ on the substrate 110 around the conductor 120 and thus the first through via V1 is effectively minimized, the chance of deformation such as warpage of the semiconductor stacking structure 100 is also effectively minimized.

In practical applications, a plurality of the semiconductor stacking structures 100 can be stacked together such that each of the semiconductor stacking structures 100 is electrically connected with the adjacent semiconductor stacking structure(s) 100, in order to form a package according to the actual conditions. Moreover, for example, the semiconductor stacking structure 100 can be a semiconductor chip or an interposer.

During the manufacture of the semiconductor stacking structure 100, the first through via V1 is first formed in the substrate 110. Then, the conductor 120 is formed in the first through via V1. Afterwards, the substrate 110 is etched to remove at least a part of the substrate 110 to form the edge 111 exposing at least one of a part of the conductor 120 and a part of the first through via V1 from the substrate 110.

Furthermore, the step of etching includes etching the conductor 120 such that the surface 121 of the conductor 120 is formed and exposed, and the exposed surface 121 is substantially flushed with the edge 111 of the substrate 110. To be more specific, the degree of etching to the conductor 120 can be adjusted, such that the shape of the cross-section of the conductor 120 can be varied. For instance, the cross-section of the conductor 120 can be a partial circle or a semi-circle. However, these shapes of the cross-section of the conductor 120 do not intend to limit the present disclosure.

In other words, as shown in FIGS. 1-2, the conductor 120 is disposed at the edge 111 of the substrate 110. Furthermore, in this embodiment, as mentioned above, the exposed surface 121 of the conductor 120 is substantially flushed with the edge 111 of the substrate 110.

In practical applications, the conductor 120 includes a metallic material such as copper. In this way, the conductor 120 is an electric conductor. On the other hand, the substrate 110 may include silicon or silicon dioxide. However, these choices of materials for the conductor 120 and the substrate 110 do not intend to limit the present disclosure. In the aspect of physical properties, since copper has a higher coefficient of thermal expansion than silicon, the respective degrees of shrinkage of the conductor 120 and the substrate 110 after cooling down in consequence of the manufacturing process in a relatively higher temperature are different.

In addition, the semiconductor stacking structure 100 includes a dielectric layer 190. The dielectric layer 190 at least partially surrounds the conductor 120. In other words, there exists at least a part of the dielectric layer 190 between the conductor 120 and the substrate 110.

Furthermore, in this embodiment, the semiconductor stacking structure 100 includes a passivation layer 130. The passivation layer 130 is disposed on the substrate 110. The passivation layer 130 has at least one second through via V2. The second through via V2 is formed at an edge 131 of the passivation layer 130 and the second through via V2 is communicated with the first through via V1, in which the conductor 120 is further present in the second through via V2.

To be more specific, during the manufacture of the semiconductor stacking structure 100, the second through via V2 is formed in the passivation layer 130. As mentioned above, the second through via V2 is communicated with the first through via V1. Then, the conductor 120 is formed in the second through via V2. Afterwards, the passivation layer 130 is etched to remove at least a part of the passivation layer 130 to form the edge 131. Meanwhile, at least a part of the conductor 120 is exposed from the passivation layer 130.

According to the actual conditions, during the manufacture of the semiconductor stacking structure 100, after the passivation layer 130 is disposed on the substrate 110, the first through via V1 is formed on the substrate 110 and the second through via V2 is formed in the passivation layer 130 in the same stage of procedure. Then, the conductor 120 is also formed in the first through via V1 and the second through via V2 in the same stage of procedure. Afterwards, the etching of the substrate 110 and the passivation layer 130 is also carried out in the same stage of procedure.

In practical applications, the substrate 110 is made thin by removing a part of the substrate 110 away from the passivation layer 130. According to the actual conditions, the step of thinning of the substrate 110 can be carried out before the step of etching or after the step of etching.

Furthermore, in this embodiment, the semiconductor stacking structure 100 includes at least one metallic pad 140. As shown in FIGS. 1-2, the metallic pad 140 is disposed on the passivation layer 130 away from the edge 131 of the passivation layer 130. In addition, the semiconductor stacking structure 100 includes a bump 150. In this embodiment, the bump 150 is disposed on the metallic pad 140.

Furthermore, the semiconductor stacking structure 100 includes a first redistribution line (RDL) 160. The first redistribution line 160 is disposed on the passivation layer 130, in which the metallic pad 140 is electrically connected with the conductor 120 through the first redistribution line 160. Furthermore, in this embodiment, the bump 150 covers at least a portion of the first redistribution line 160.

Similarly, as shown in FIG. 2, the semiconductor stacking structure 100 includes a second redistribution line 180. The second redistribution line 180 is disposed on a surface 112 of the substrate 110 away from the passivation layer 130, and the second redistribution line 180 is electrically connected with the conductor 120.

Reference is made to FIG. 3. FIG. 3 is a sectional view of a semiconductor stacking structure 100 according to another embodiment of the present disclosure. In this embodiment, the semiconductor stacking structure 100 includes a metallic structure 170. As shown in FIG. 3, the metallic structure 170 is embedded in the passivation layer 130, in which the metallic pad 140 is electrically connected with the conductor 120 through the metallic structure 170.

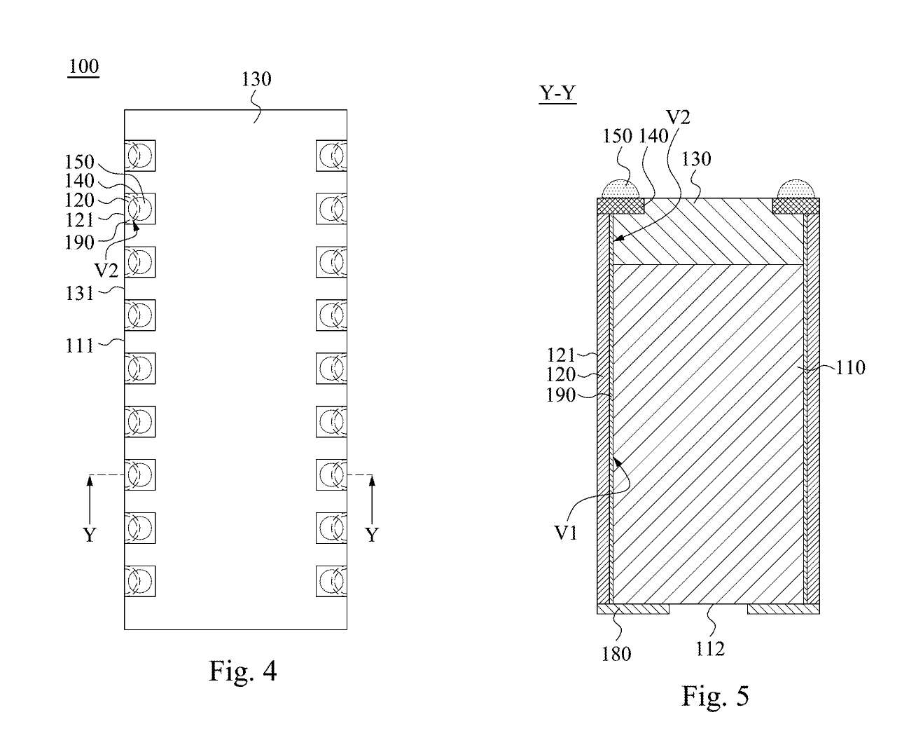

Reference is made to FIGS. 4-5. FIG. 4 is a top view of a semiconductor stacking structure 100 according to a further embodiment of the present disclosure. FIG. 5 is a sectional view along the section line Y of FIG. 4. As shown in FIGS. 4-5, the metallic pad 140 is located at the edge 131 of the passivation layer 130, and the metallic pad 140 directly contacts the conductor 120. In other words, the metallic pad 140 is electrically connected with the conductor 120 as well.

In conclusion, when compared with the prior art, the aforementioned embodiments of the present disclosure have at least the following advantages:

(1) Since the surface of the conductor is exposed to the air, even if the conductor present in the first via shrinks after the conductor is cooled down in consequence of the manufacturing process in a relatively higher temperature, the stress that the conductor exerts on the substrate because of the shrinkage of the conductor is effectively minimized. As a result, the size of the KOZ is also effectively minimized. Therefore, more amount of area on the substrate can be used for disposing electronic components such as transistors.

(2) Since the size of the KOZ on the substrate around the conductor and thus the through via is effectively minimized, the chance of deformation such as warpage of the semiconductor stacking structure is also effectively minimized.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

1. A semiconductor stacking structure, comprising:
a substrate having at least one first through via formed at an edge of the substrate;
at least one conductor present in the first through via, at least one of the conductor and the first through via is exposed from the edge of the substrate;
a passivation layer disposed on the substrate and having at least one second through via formed at an edge of the passivation layer and communicated with the first through via, wherein the conductor is further present in the second through via; and
a dielectric layer located between the conductor and the substrate, and between the conductor and the passivation layer.

2. The semiconductor stacking structure of claim 1, wherein the conductor is flushed with the edge of the substrate.

3. (canceled)

4. The semiconductor stacking structure of claim 1, further comprising:
at least one metallic pad disposed on the passivation layer and contacting the conductor.

5. The semiconductor stacking structure of claim 4, further comprising:
a bump disposed on the metallic pad.

6. The semiconductor stacking structure of claim 1, further comprising:
at least one metallic pad disposed on the passivation layer away from the edge of the passivation layer and electrically connected with the conductor.

7. The semiconductor stacking structure of claim 6, further comprising:
a first redistribution line disposed on the passivation layer, wherein the metallic pad is electrically connected with the conductor through the first redistribution line.

8. The semiconductor stacking structure of claim 7, further comprising:
a bump disposed on the metallic pad and covering at least a portion of the first redistribution line.

9. The semiconductor stacking structure of claim 6, further comprising:
a metallic structure embedded in the passivation layer, wherein the metallic pad is electrically connected with the conductor through the metallic structure.

10. The semiconductor stacking structure of claim 1, further comprising:
a second redistribution line disposed on a surface of the substrate away from the passivation layer.

11. The semiconductor stacking structure of claim 1,
wherein the dielectric layer at least partially surrounds the conductor.

12. A method for manufacturing a semiconductor stacking structure, comprising:
forming a first though via in a substrate;
forming a conductor in the first through via; and
etching the substrate to remove at least a part of the substrate to form an edge exposing at least one of a part of the conductor and a part of the first through via.

13. The method of claim 12, wherein the etching comprises:
etching the conductor such that the conductor is flushed with the edge of the substrate.

14. The method of claim 12, further comprising:
forming a second through via communicated with the first through via in a passivation layer disposed on the substrate;
forming the conductor in the second through via; and
etching the passivation layer to remove at least a part of the passivation layer such that at least a part of the conductor is exposed from the passivation layer.
